(19) United States
(12) Patent Application Publication
(10) Pub. No.: US 2008/0124904 A1
(43) Pub. Date: May 29, 2008

(54) Method for Fabricating Semiconductor Device

(76) Inventor: HYUN SOO SHIN, Seongdong-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/773,180

(22) Filed: Jul. 3, 2007

(30) Foreign Application Priority Data
Jul. 4, 2006 (KR) 10-2006-0062268

(51) Int. Cl. H01L 21/265

(52) U.S. Cl. 438/531; 257/E21.334

(57) ABSTRACT

Provided is a method for fabricating a semiconductor device. The method includes implanting ions into an n-channel metal oxide semiconductor (NMOS) region of a semiconductor substrate so as to form a channel. The implanting can be performed by implanting boron ions at an ion implanting energy of 20 keV to 100 keV using a photoresist layer formed on the semiconductor substrate as an ion implanting mask for inhibiting ions from entering the semiconductor substrate below the photoresist layer. The photoresist layer can be a mid-ultra-violet photoresist having a reduced thickness.

### CROSS-REFERENCE TO RELATED APPLICATION

The present application claims the benefit under 35 U.S.C. § 119 of Korean Patent Application No. 10-2005-0062268, filed Jul. 4, 2006, which is hereby incorporated by reference in its entirety.

### BACKGROUND

As the integration level of semiconductor devices increases and the design rule of the semiconductor devices decreases, process margins become smaller.

In general, for 130 nm and above technologies a mid-ultra-violet (MUV) photoresist (PR) is used to mask regions of a substrate during the manufacturing process. However, in 90 nm and lower technologies, where the design widths are narrower, the conventional photoresist having a thickness (typically 15,000 Å) to block ion implantation may not be developed fully because of lack of exposure and depth of focus issues due to the narrow pattern widths. In addition, photoresist development problems may also cause opening failures. Therefore, when channel implantation is performed using a 15,000 Å photoresist layer during a manufacturing process of a 90 nm or smaller device, sufficient process margins cannot be obtained, thereby making the device unstable. Particularly, it is very difficult to perform the channel implantation on a 90-nm device. For this reason, the use of a deep ultra violet (DUV) process is generally performed.

However, the DUV process increases the manufacturing costs of a semiconductor device. Thus, this problem should be solved.

FIGS. 1 and 2 are views for explaining a channel implantation operation according to the related art.

Referring to FIG. 1, shallow trench isolations (STIs) 11 are formed in a semiconductor substrate 10, and active regions such as an n-channel metal oxide semiconductor (NMOS) region and a p-channel metal oxide semiconductor (PMOS) region are defined in the semiconductor substrate 10 according to the STIs 11.

A photoresist layer 20 is formed on the semiconductor substrate 10 and the STIs 11. The photoresist layer 20 includes an opening for implanting ions into the semiconductor substrate 10.

Thereafter, an ion implantation operation is performed to form a channel in the NMOS region. In the ion implantation process, boron ions are implanted into the semiconductor substrate 10 through the opening of the photoresist layer 20.

The channel is used as a path for carriers. After the boron ion implantation operation, the photoresist layer 20 is removed for performing the following operations.

However, after the photoresist layer 20 is removed, the boron ions can exist in the PMOS region of the semiconductor substrate 10 as shown in FIG. 2 (refer to 2A and 2B).

To prevent this problem, the photoresist layer 20 has a relatively large thickness of 15,000 Å to block boron ions directed to the PMOS region of the semiconductor substrate 10 when the boron ions are implanted into the NMOS region of the semiconductor substrate 10 through the opening of the photoresist layer 20. Alternatively, a DUV process is used for the same reason.

However, in both cases, the manufacturing costs of a semiconductor device increase, and the manufacturing process efficiency of the semiconductor decrease.

### BRIEF SUMMARY

Embodiments provide optimal process conditions for an ion implantation operation so that the thickness of a photoresist layer can be reduced, and the ion blocking ability of the photoresist layer can be increased.

In one embodiment, a method for fabricating a semiconductor device includes implanting ions into an n-channel metal oxide semiconductor (NMOS) region of a semiconductor substrate by implanting boron ions at an ion implanting energy of 20 keV to 100 keV using a photoresist layer formed on a p-channel metal oxide semiconductor (PMOS) region of the semiconductor substrate as an ion implanting mask. The photoresist can be a MUV photoresist having a reduced thickness.

### BRIEF DESCRIPTION OF THE DRAWINGS

FIGS. 1 and 2 are views for explaining a channel implantation operation according to the related art.

FIG. 3 is a view for explaining an ion implantation operation according to an embodiment.

FIGS. 4 to 9 are graphs showing measurement results of blocking effects of photoresist for various process conditions.

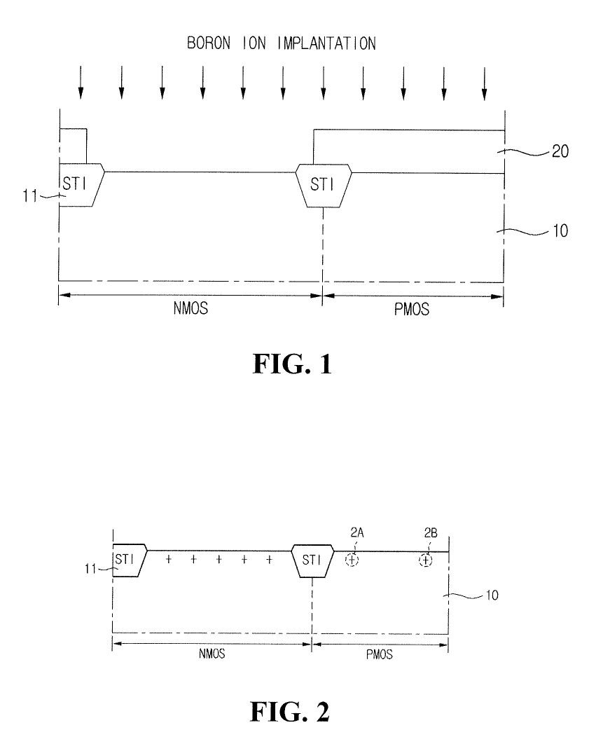

### DETAILED DESCRIPTION

Embodiments relate to a semiconductor device, and more particularly, to a method for fabricating a semiconductor device with sufficient photolithographic margins.

Hereinafter, embodiments will be described in detail with reference to the accompanying drawings.

Embodiments of the present invention provide conditions for a boron ion implantation operation that inhibit boron ions from being implanted into a semiconductor substrate directly through a photoresist layer when the thickness of the photoresist layer is reduced.

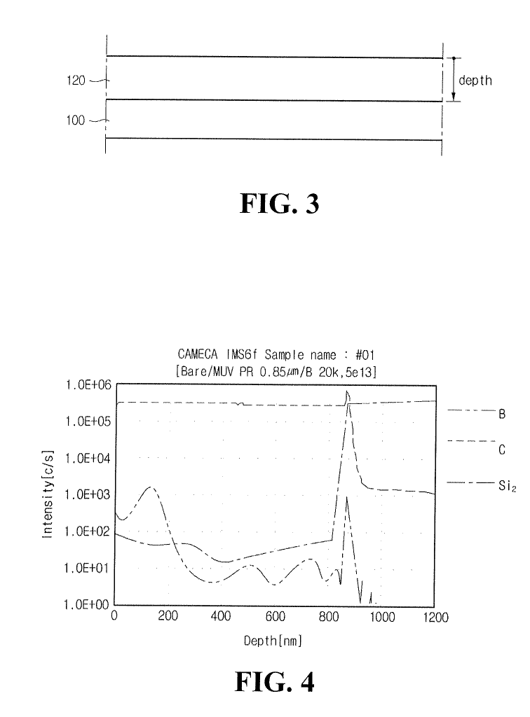

FIG. 3 is a view for explaining an ion implantation operation according to an embodiment, and FIGS. 4 to 9 are graphs showing measurement results of blocking effects of photoresist for various process conditions.

Referring to FIG. 3, a photoresist layer 120 can be formed on a substrate 100 to a predetermined thickness.

The photoresist layer 120 is used as an ion implanting mask during an ion implantation operation. During the ion implantation operation, the photoresist layer 120 functions as a blocking layer for preventing ions from being implanted into a portion of the substrate 100 located under the photoresist layer 120.

As explained above, a p-channel metal oxide semiconductor (PMOS) region and an n-channel metal oxide semiconductor (NMOS) region can be defined in the substrate 100. When a channel implantation operation is performed to create P-wells for the NMOS region of the substrate 100, the photoresist layer 120 inhibits p-type impurity ions such as boron ions from being implanted into the PMOS region of the substrate 100.

In FIGS. 4 to 9, each horizontal axis (an x-axis) denotes a depth measured in a vertical direction from the top surface of the photoresist layer 120.

Although a 15,000 Å photoresist layer is used in the related art, the photoresist layer 120 according to an embodiment of the present invention has a thickness of 8,500 Å. Blocking characteristics of the photoresist layer 120 are measured for various process conditions to find optimal process conditions under which the photoresist layer 120 can efficiently block impurity ions.

Referring to FIG. 4, the photoresist layer 120 is formed to a thickness of 8,500 Å, and 5×10¹³ ions/cm² of boron ions are implanted into the photoresist layer 120 at an ion implantation energy of 20 keV.

As shown in FIG. 4, the intensity of carbon C representing the photoresist layer 120 is constant when the depth ranges from 0 Å to 8,500 Å and steeply decreases after the depth reaches 8,500 Å.

The intensity of boron ions B is larger than a selected value when the depth ranges from 0 Å to 8,500 Å. However, when the depth is larger than 8,500 Å, the intensity of the boron ions B is almost zero.

The boron ions B are not implanted into a portion of the substrate 100 located under the photoresist layer 120. That is, all the boron ions B are blocked by the photoresist layer 120.

Therefore, under the process conditions of FIG. 4 (i.e., the dose of boron ions is 5×10¹³ ions/cm², and the ion implanting energy is 20 keV), the photoresist layer 120 can efficiently block the boron ions although the photoresist layer 120 has a reduced thickness of 8,500 Å.

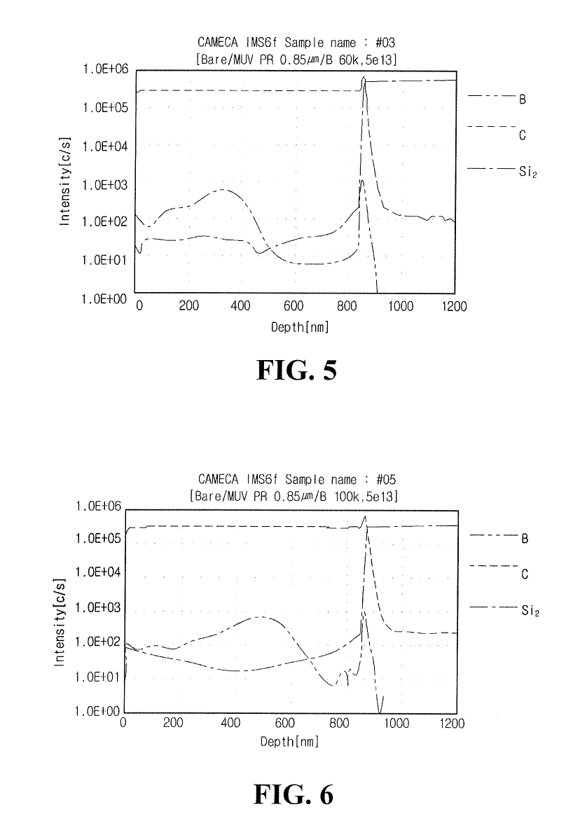

Referring to FIG. 5, the photoresist layer 120 is formed to a thickness of 8,500 Å, and 5×10¹³ ions/cm² of boron ions are implanted into the photoresist layer 120 at an ion implantation energy of 60 keV.

As shown in FIG. 5, the intensity of carbon C representing the photoresist layer 120 is constant when the depth ranges from 0 Å to 8,500 Å and steeply decreases after the depth reaches 8,500 Å.

The intensity of boron ions B is larger than a predetermined value when the depth ranges from 0 Å to 8,500 Å. However, when the depth is larger than 8,500 Å, the intensity of the boron ions B is almost zero.

The boron ions B are not implanted into a portion of the substrate 100 located under the photoresist layer 120. That is, all the boron ions B are blocked by the photoresist layer 120 like in the case of FIG. 4.

Referring to FIG. 6, the photoresist layer 120 was formed to a thickness of 8,500 Å, and 5×10¹³ ions/cm² of boron ions are implanted into the photoresist layer 120 at an ion implantation energy of 100 keV.

As shown in FIG. 6, the intensity of carbon C representing the photoresist layer 120 is constant when the depth ranges from 0 Å to 8,500 Å and steeply decreases after the depth reaches 8,500 Å.

The intensity of boron ions B is larger than a selected value when the depth ranges from 0 Å to 8,500 Å. However, when the depth is larger than 8,500 Å, the intensity of the boron ions B is almost zero.

The boron ions B are not implanted into a portion of the substrate 100 located under the photoresist layer 120. That is, all the boron ions B are blocked by the photoresist layer 120 like in the cases of FIGS. 4 and 5.

It can be understood from the experiments illustrated in FIGS. 4, 5, and 6 that the photoresist layer 120 having a reduced thickness can efficiently block ions when the ion implanting energy ranges from 20 keV to 100 keV.

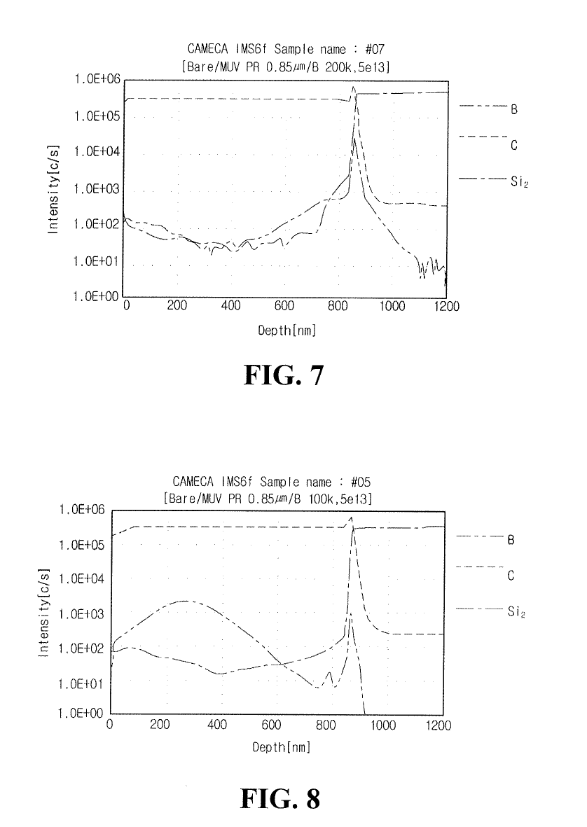

Referring to FIG. 7, the photoresist layer 120 is formed to a thickness of 8,500 Å, and 5×10¹³ ions/cm² of boron ions are implanted into the photoresist layer 120 at an ion implantation energy of 200 keV.

As shown in FIG. 7, the intensity of carbon C representing the photoresist layer 120 is constant when the depth ranges from 0 Å to 8,500 Å and steeply decreases after the depth reaches 8,500 Å.

The intensity of boron ions B is larger than a selected value when the depth ranges from 0 Å to 8,500 Å. Furthermore, even when the depth is larger than 8,500 Å, the intensity of the boron ions B does not reduce to zero (i.e., the intensity of the boron ions B is larger than a selected value).

This means that the boron ions B are implanted through the photoresist layer 120 into a portion of the substrate 100 located under the photoresist layer 120 when the ion implanting energy is 200 keV.

Therefore, when the photoresist layer 120 has a thickness of 8,500 Å, it is undesirable that the boron ions are implanted at an ion implanting energy of 200 keV.

That is, when the ion implanting energy is 200 keV, the photoresist layer 120 having a thickness of 8,500 Å cannot efficiently block the boron ions from entering the substrate through the photoresist layer 120. Therefore, it is undesirable for highly-integrated semiconductor devices.

Referring to FIG. 8, the photoresist layer 120 is formed to a thickness of 8,500 Å, and 2×10¹⁴ ions/cm² of boron ions are implanted into the photoresist layer 120 at an ion implantation energy of 60 keV.

As shown in FIG. 8, the intensity of carbon C representing the photoresist layer 120 is constant when the depth ranges from 0 Å to 8,500 Å and steeply decreases after the depth reaches 8,500 Å.

The intensity of boron ions B is larger than a selected value when the depth ranges from 0 Å to 8,500 Å. However, when the depth is larger than 8,500 Å, the intensity of the boron ions B is almost zero.

The boron ions B are not implanted into a portion of the substrate 100 located under the photoresist layer 120. That is, all the boron ions B are blocked by the photoresist layer 120.

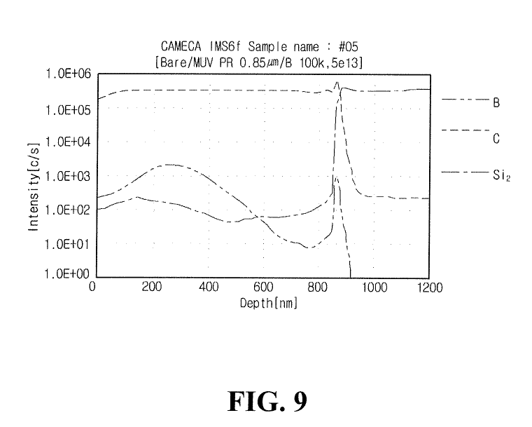

Referring to FIG. 9, the photoresist layer 120 is formed to a thickness of 8,500 Å, and 2×10¹⁴ ions/cm² of boron ions are implanted into the photoresist layer 120 at an ion implantation energy of 100 keV.

As shown in FIG. 9, the intensity of carbon C representing the photoresist layer 120 is constant when the depth ranges from 0 Å to 8,500 Å and steeply decreases after the depth reaches 8,500 Å.

The intensity of boron ions B is larger than a selected value when the depth ranges from 0 Å to 8,500 Å. However, when the depth is larger than 8,500 Å, the intensity of the boron ions B is almost zero.

The boron ions B are not implanted into a portion of the substrate 100 located under the photoresist layer 120. That is, all the boron ions B are blocked by the photoresist layer 120.

It can be understood from the above-described experimental results that when 5×10¹³ to 2×10¹⁴ of ions are implanted at an implanting energy of 20 keV to 100 keV, the photoresist layer can efficiently block ions even when the thickness of the photoresist layer is 8,500 Å.

In the above-described embodiments, the photoresist layer 120 is formed to a thickness of 8,500 Å, and a plurality of experiments is performed. However, as shown in the accompanying drawings, when the photoresist layer 120 is formed to a thickness of 8,500 Å±500 Å, the same or similar effect may be obtained.

The examples provide a method of fabricating a semiconductor device. According to an embodiment of a method of fabrication a semiconductor device, the thickness of the photoresist layer used for ion implantation can be reduced, and the ion blocking ability of the photoresist layer can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for fabricating a semiconductor device, the method comprising:
implanting ions into an n-channel metal oxide semiconductor (NMOS) region of a semiconductor substrate to form a p-type channel,
wherein the implanting is performed by implanting boron ions at an ion implanting energy of 20 keV to 100 keV using a photoresist layer formed on the semiconductor substrate as an ion implanting mask.

2. The method according to claim 1, wherein the photoresist layer has a thickness of about 8,500 Å.

3. The method according to claim 2, wherein the photoresist layer comprises a mid-ultra-violet photoresist.

4. A method of fabricating a semiconductor device, the method comprising:
forming a photoresist layer pattern on a semiconductor substrate; and
implanting dopant ions into the semiconductor substrate using the photoresist layer pattern as an ion implanting mask,
wherein the dose of the dopant ions ranges in amount from 5×10¹³ to 2×10¹⁴ ions/cm² and are implanted at an ion implanting energy of 20 keV to 100 keV.

5. The method according to claim 4, wherein the photoresist layer pattern has a thickness of 8,500 Å±500 Å.

6. The method according to claim 4, wherein implanting the dopant ions forms a p-type channel by implanting boron ions for the p-type channel.

7. The method according to claim 4, wherein the photoresist layer pattern prevents dopant ions from being implanted into the substrate below the photoresist layer pattern.

8. The method according to claim 4, wherein forming the photoresist layer pattern on the semiconductor substrate comprises:
depositing a mid-ultra-violet photoresist on the substrate, and
performing a photolithography process to expose predetermined regions of the substrate.
